(19) United States
(12) Patent Application Publication
(10) Pub. No.: US 2025/0291010 A1
(43) Pub. Date: Sep. 18, 2025

(54) SENSOR ELEMENT, TEST DEVICE, AND METHOD FOR TESTING A DATA CARRIER HAVING A SPIN RESONANCE FEATURE

(71) Applicant: GIESECKE+DEVRIENT CURRENCY TECHNOLOGY GMBH, Munchen (DE)

(72) Inventor: Stephan HUBER, Munchen (DE)

(21) Appl. No.: 18/862,673

(22) PCT Filed: May 5, 2023
(86) PCT No.: PCT/EP2023/025212

§ 371 Date: Nov. 4, 2024

(30) Foreign Application Priority Data
May 6, 2022 (DE) 10 2022 001 592.7

(51) Int. Cl. G01R 33/345; G01R 33/36; G01R 33/60; G07D 7/04

(52) U.S. Cl. CPC G01R 33/3456; G01R 33/3635; G01R 33/60; G07D 7/04

(57) ABSTRACT

A sensor element for testing a flat-surface data carrier has a spin resonance feature. The sensor element includes a magnetic core with an air gap, into which the flat-surface data carrier can be inserted for testing, a polarization device for generating a static magnetic flux in the air gap, and a resonator device for exciting the spin resonance feature of the data carrier to be tested in the air gap. The resonator device contains at least two stripline resonators, which are designed and configured to be operated at different excitation frequencies.

The invention relates to a sensor element for checking the authenticity of a flat-surface data carrier, in particular a banknote, having a spin resonance feature. The invention also relates to a test device having such a sensor element and to a method for testing authenticity using such a sensor element or such a test device.

Data carriers, such as value or identification documents, but also other valuable objects, such as brand-name articles, are often provided with security elements that allow the data carriers to be authenticated and that also serve as protection against unauthorized reproduction. It is well known in the field of machine authentication to use security elements with spin resonance features to secure documents and other data carriers. The security elements are provided with substances that have a spin resonance signature. The spin resonance signatures that can be used for authenticity testing include, in particular, nuclear magnetic resonance (NMR) effects, elec-tron spin resonance (ESR) effects, and ferromagnetic resonance (FMR) effects.

In the process of checking banknotes, three different magnetic fields are usually generated in the measuring range of a banknote processing machine, for example, to detect the spin resonance signatures. This is specifically a quasi-static polarization field B₀, which runs parallel to the axial direction (z direction) of the air gap of a magnetic circuit. A second magnetic field is formed by a modulation field B_{mod}, which also runs parallel to the z-axis and typically has a frequency f_{mod} in the kHz range. For the excitation of transitions between the split spin energy levels of the spin resonance signature substances, an excitation field B₁ is provided, which is polarized perpendicular to the B₀ direction. The excitation field oscillates at the resonance frequency of the material, which is also referred to as the Larmor frequency, and which is proportional to the polarization field B₀.

To generate the polarization field B₀, a magnetic circuit is often used that directs the magnetic flux of permanent magnets and/or coils to an air gap in which the testing of the flat-surface data carriers takes place.

A high-frequency resonator, for example a stripline resonator, is used for generating the excitation field B₁. This is a conductive structure with a characteristic length l, which is arranged on a carrier. If the wavelength λ of the coupled-in high-frequency signal matches the dimension 1 of the conducting structure during the authenticity test, a standing wave can form in the resonator and the stripline resonator is in resonance at the excitation frequency associated with the wavelength λ. Since the extension of a stripline resonator in the plane of the carrier is significantly greater than perpendicular thereto, this is also referred to as the plane of the stripline resonator, which corresponds to the plane of the carrier.

When testing a data carrier, for example in the context of an authenticity check, a spin resonance spectrum of the spin resonance feature is often determined and compared with an expected spectrum using characteristic features. Typically, spin resonance spectra are recorded in a time-consuming B₀-ramp procedure (also known as a B₀ sweep procedure). In this case, the static polarization field B₀ is slowly varied around the resonance field strength at a fixed frequency of the excitation field B₁, and thus the field strength of the polarization field B₀ is traversed. Since the Larmor frequency of a spin resonance feature to be tested is proportional to the polarization field strength B₀, the excitation frequency is effectively shifted towards the Larmor frequency, which allows the recording of a frequency spectrum of the spin resonance feature. Since the temporal change in the field strength of the polarization field B₀ is much slower in the B₀-ramp procedure than the temporal change in the modulation field B_{mod} and the excitation field B₁, in the context of this application B₀ is also referred to as a static magnetic field or static magnetic flux, even if a ramp field is present.

In particular in high-speed banknote processing machines, however, the sensor operation requires short measuring times, which are not sufficient to allow the complete spectrum of a spin resonance feature to be measured with a ramp (often also: sweep). Frequency spectra can then only be recorded with a few measuring points, i.e. with low resolution or over a narrow frequency band. For many applications, however, a high spectral resolution, broadband measurement is desirable, for example, in order to be able to distinguish characteristic substances with different Larmor frequencies. At high spectral resolution, spin resonance features with spectral code, for example for different currencies or different denominations, can also be used.

Based on this, the object of the invention is to provide an improved device for testing data carriers with spin resonance features, and in particular to provide a sensor element that allows a spectrally high-resolution and/or broadband measurement of the spin resonance of a data carrier to be tested in a short time.

This object is achieved by means of the features of the independent claims. Developments of the invention are the subject of the dependent claims.

The invention provides a sensor element for testing, in particular testing the authenticity, of a flat-surface data carrier having a spin resonance feature. The flat-surface data carrier can be a banknote, for example. The sensor element contains a magnetic core with an air gap, into which the flat-surface data carrier can be inserted for testing, a polarization device for generating a static magnetic flux in the air gap, and a resonator device for exciting the spin resonance feature of the data carrier to be tested in the air gap. The spin resonance feature is preferably an ESR feature.

The resonator device contains at least two stripline resonators, which are designed and configured to be operated at different excitation frequencies. For example, the excitation frequencies of the at least two stripline resonators differ by at least 1%, preferably by at least 2%.

As explained in more detail below, the arrangement of multiple stripline resonators that are operated at different excitation frequencies allows the simultaneous measurement of the spin resonance at multiple different frequencies, thus allowing for higher spectral resolution and/or shorter measurement times. The requirements on a field ramp for measuring a spectral line are also significantly reduced.

In principle, the stripline resonators used are characterized in particular in that their sensi-tive region is very easily accessible and that they have a very high filling factor for flat-surface samples, such as those formed by the banknotes to be tested. The stripline resonators are some-times referred to below as resonators purely for brevity.

In an advantageous embodiment, the stripline resonators of the resonator device are arranged in the form of a one-dimensional array. In a test device, the one-dimensional array is in particular parallel to a transport path of the data carrier, so that the stripline resonators of the moving data carrier are swept over consecutively.

In another, also preferred embodiment, the stripline resonators of the resonator device form a multi-track arrangement with a plurality of parallel tracks, in which each track is formed by a one-dimensional array of stripline resonators.

The resonator device may in particular contain two, three, four, five or six stripline resonators, wherein a larger number of stripline resonators, for example a multi-track arrangement with two or three tracks each having five stripline resonators, may also be advantageous. Increasing the number of stripline resonators has the advantage of better spectral resolution or a shorter required measurement time.

In an advantageous embodiment, the stripline resonators of the resonator device all have different resonance frequencies. In particular, the resonance frequencies may be distributed equi-distantly so that for a number of N resonators the resonance frequency for the i-th resonator is given by the relation

$${f}_{i} = {f}_{0} + ( i - 1 ) * Δ f ,$$

with i=1, . . . , N, with a minimum frequency f₀ and a constant frequency interval Δf. The resonator with the high-est frequency has a resonance frequency of f_{N}=f₀+(N−1)*Δf. For example, the resonance frequencies of at least two stripline resonators differ by at least 1%, preferably by at least 2%. In order to increase the signal-to-noise ratio, multiple stripline resonators at each of the frequencies fᵢ may also be provided.

The stripline resonators are advantageously designed geometrically similar, and so have the same shape but different sizes. In particular, the stripline resonators may have different edge lengths, for example, square stripline resonators of different edge length l may be provided or rectangular stripline resonators with different edge lengths lₓ, l_{y}, but the same aspect ratio lₓ/l_{y}, or rectangular stripline resonators with different length but the same width.

The air gap mentioned is advantageously bounded by two plane-parallel pole surfaces of the magnetic core. At the pole surfaces, the magnetic core is preferably made of a ferromagnetic material with a magnetic permeability μᵣ>>1, that is, in particular μᵣ greater than 1×10², but the pole surfaces can also be made of a paramagnetic material with μᵣ≈1, in particular, μᵣ is not more than 1+10⁻². The polarization device advantageously generates a static magnetic flux in the air gap, which is substantially of the same strength at the location of each of the stripline resonators. In particular, it is provided that the static magnetic flux at the location of the stripline resonators has a maximum deviation of 2%.

The stripline resonators are advantageously planar in design, with a main extension plane which is plane-parallel to at least one of the pole surfaces of the magnetic core bounding the air gap. The main extension plane is further advantageously perpendicular to the direction of the static magnetic flux generated by the polarization device. In this description, the direction of the static magnetic flux is also referred to as the z-direction. The main extension plane of the stripline resonators then extends in the x-y plane perpendicular to the z-direction.

In an advantageous embodiment, the sensor element further comprises a modulation device for generating a time-varying magnetic modulation field in the air gap, wherein the modulation frequency is preferably equal in all stripline resonators of the resonator device. For example, the modulation frequency at the location of any two stripline resonators differs by a maximum of 2% from each other. The modulation device is advantageously formed by a single modulation coil arranged in the air gap, in particular a single flat-surface coil.

The air gap advantageously has a height, i.e. a dimension in the z-direction, of less than 10 mm, preferably of less than 5 mm. This allows a particularly strong polarization field, i.e. a strong static magnetic flux, to be generated in the air gap.

In an advantageous development of the invention, at least some of said stripline resonators, configured and designed for operation at different resonance frequencies, are each replaced by an N×M array of stripline resonators to increase the signal-to-noise ratio, where N and M are natural numbers and at least one of the values of N and M is greater than 1, wherein the stripline resonators of the N×M array are all fed from the same signal source and are electrically connected in parallel and/or in series.

In a particularly advantageous embodiment, the sensor element further comprises a ramp coil for generating a ramp function of the static magnetic flux.

The resonator device is advantageously designed for the excitation of spin resonance signals with a frequency above 1 GHz, in particular between 1 GHz and 10 GHz. Compared to lower frequencies, this allows a higher spectral resolution and a stronger measurement signal.

The resonator device is also designed in particular for detecting spin resonance signals of the spin resonance feature. The resonator device can in particular record a response signal of the spin resonance feature and output it to a detector. The spin resonances can be determined, for example, with a continuous wave (CW) method, a pulsed method, or a rapid scan method.

The stripline resonators can be operated both in reflection and in transmission when testing the data carrier. The latter has the advantage that no element such as a circulator is required in the signal branch, which separates the signals leading from and returning to the resonator.

Advantageously, the resonator device comprises a flat-surface carrier on which the stripline resonators are applied. The carrier is conveniently formed by a printed circuit board, which allows for reproducible and cost-effective production. However, it is also advantageous, in particular to reduce dielectric losses in the carrier material, to use carriers based on ceramic, Tef-lon or hydrocarbons.

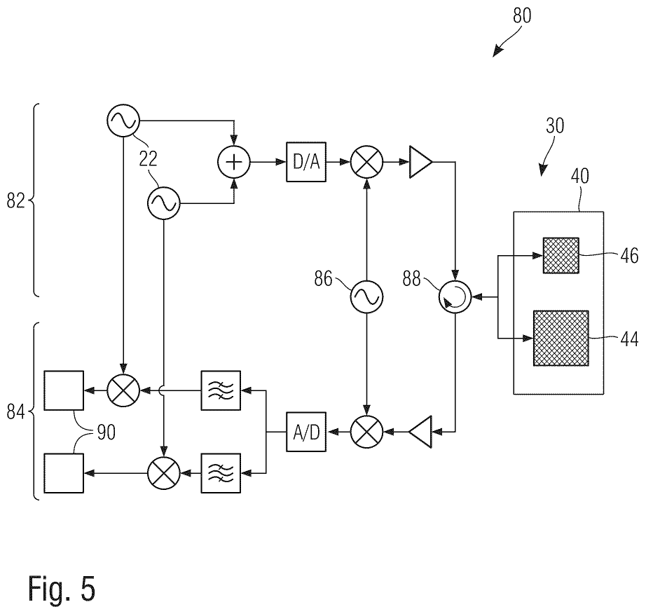

The invention also includes a test device for testing a flat-surface data carrier, in particular a banknote, having a spin resonance feature using a sensor element of the type described above. In addition, the test device comprises either a plurality of signal sources having different excitation frequencies, which are used to feed the stripline resonators of the resonator device, or a single signal source with an excitation signal having multiple different frequency components from which the stripline resonators are fed. In the latter case, the resonator device expediently comprises stripline resonators having different resonance frequencies, each of which corresponds to one of the frequency components of the excitation signal so that each of the stripline resonators is excited at its resonance frequency by the matching frequency component of the excitation signal. This is explained in more detail in connection with FIG. 5 with reference to an exemplary embodiment.

Advantageously, the test device further comprises a transport device which guides the flat-surface data carriers to be tested along a transport path through the air gap of the magnetic core. The transport device is designed and configured in particular for high-speed transport, for example between 1 m/s and 12 m/s, of the flat-surface data carriers to be tested along the transport path.

The invention also includes a method for testing a flat-surface data carrier, in particular a banknote, having a spin resonance feature by means of a sensor element of the described type or a test device of the described type, wherein in the method
a flat data carrier to be tested is guided along a transport path through the air gap of the magnetic core of said sensor element, wherein a plurality of stripline resonators of the resonator device are located one behind the other parallel to the transport path,
a static magnetic flux is generated using the polarization device and a time-varying magnetic modulation field is generated in the air gap preferably using a modulation device, and
the resonator is used to excite the spin resonance feature of the data carrier to be tested.

In an advantageous sequence of the method, it is provided that
the data carrier to be tested is passed by the successive stripline resonators, and a time series of measurements of the response signal of the spin resonance feature generated after excitation is recorded by the stripline resonators,
measurement data corresponding to the same measuring spot are identified from the time series of measurements of the stripline resonators,
spectral information relating to the spin resonance feature is derived from the identified measurement data, and
the data carrier is evaluated on the basis of the derived spectral information, in particular for authenticity and/or membership of a data carrier class.

The measurement data are advantageously spatially resolved or spatially averaged.

According to an advantageous development of the method, it is provided that
a spatially homogeneous ramping field is superimposed on the static magnetic flux so that the total static magnetic flux in the air gap varies over time between a minimum value and a maximum value,
the spectral information is derived from the identified measurement data, taking into account the field strength of the static magnetic flux at the respective measurement time, and
based on the derived spectral information, the authenticity of the tested data carrier and/or the membership of the tested data carrier of one of a plurality of data carrier classes with different spectral signatures is determined.

As described, in a preferred embodiment the stripline resonators are arranged one after another along a transport direction of the data carrier. This has the advantage that all resonators measure the same track on the data carrier, i.e. with a certain time offset, the same measuring points. This facilitates the evaluation and testing of the data carrier.

A multi-track structure for generating a spatial resolution transverse to the transport direction is also advantageous. For this purpose, multiple tracks are constructed each with a one-dimensional array of resonators for the spectral resolution.

Further exemplary embodiments as well as advantages of the invention are explained below by reference to the figures, in the representation of which a true-to-scale and proportional reproduction has been omitted in order to increase the clarity.

In the drawings:

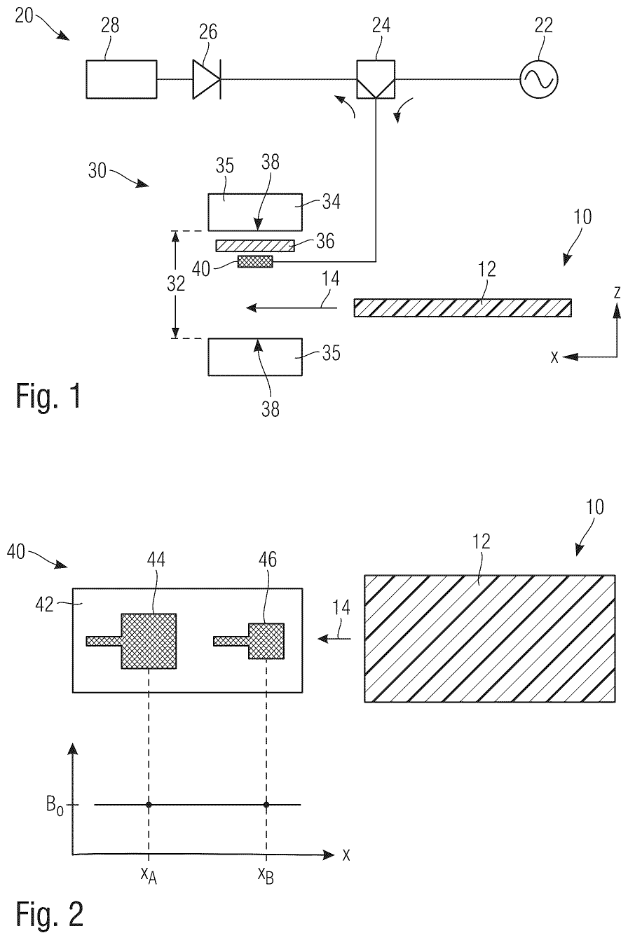

FIG. 1 schematically shows a test device of a banknote processing system for the measurement of spin resonances of a banknote test specimen,

FIG. 2 in the upper part, schematically shows a plan view of the resonator device of the test device of FIG. 1 and the supplied banknote test specimen and in the lower part, schematically, the plot of the homogeneous polarization field,

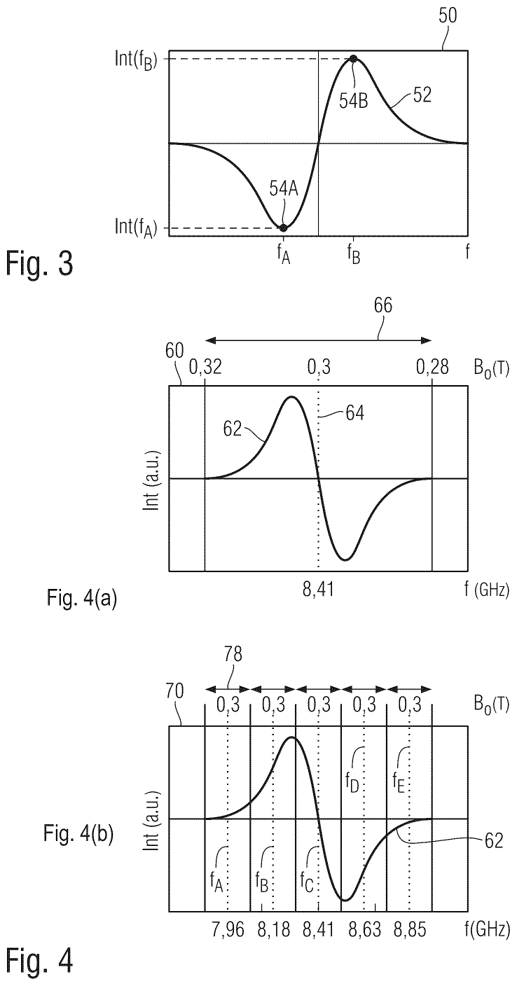

FIG. 3 shows the simplified spectrum of a spin resonance line as a function of the excitation frequency at a fixed value of the polarization field,

FIG. 4 shows diagrams illustrating the recording of the spin resonance spectrum of the spin resonance line of FIG. 3, in (a) with a conventional sensor element and in (b) with a sensor element according to the invention,

FIG. 5 shows a circuit for connecting the resonator device of a sensor element according to the invention with only one single signal branch,

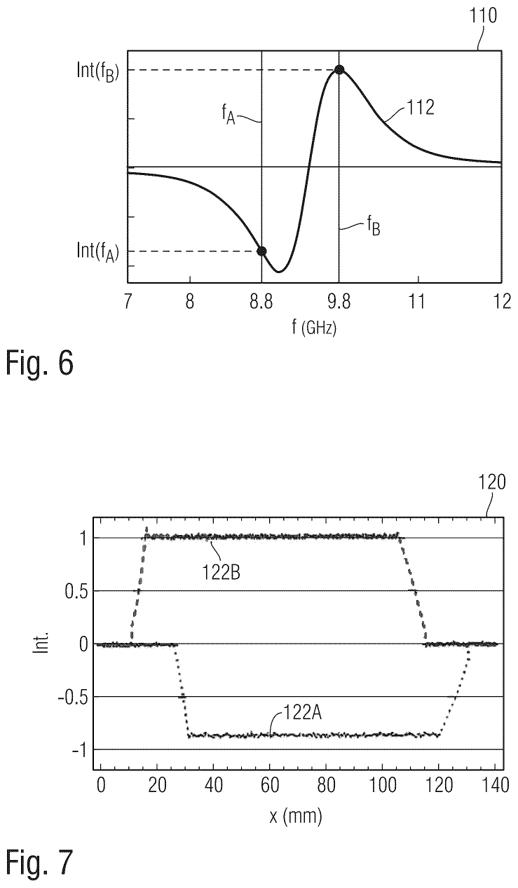

FIG. 6 shows the spectrum of the spin resonance feature of a paper sample, and

FIG. 7 shows signal curves during the measurement of the spin resonance feature of FIG. 6 with a sensor element according to the invention.

The invention will now be explained using the example of the authenticity testing of banknotes. FIG. 1 schematically shows a test device 20 of a banknote processing system for the measurement of spin resonances of a banknote test specimen 10.

The banknote test specimen 10 contains a spin resonance feature 12, the characteristic properties of which are used to prove the authenticity of the banknote. The spin resonance feature may be present only in a sub-region of the banknote or, as in the exemplary embodiment shown, may also extend over the entire surface of the banknote test specimen.

The test device 20 contains a sensor element 30 with a magnetic core 35, which has an air gap 32 bounded by two pole surfaces 38, through which the banknote test specimen 10 is guided along a transport path 14 during the authenticity test.

For the detection of spin resonance signatures of the spin resonance feature 12, the sensor element 30 generates three different magnetic fields in a measuring range of the air gap 32.

Firstly, a homogeneous, static magnetic flux is generated parallel to the z-axis in the measuring range by a polarization device 34. In order to generate a strong polarization field, the height of the air gap in the z direction is advantageously less than 10 mm, in particular even less than 5 mm.

Secondly, a modulation device 36 generates a time-varying magnetic modulation field in the air gap, which also runs parallel to the z-axis and has a modulation frequency f_{Mod} in the range between 1 kHz to 1 MHz. Finally, a resonator device 40 arranged in the air gap 32 generates an excitation field B₁, which induces energy transitions between the spin energy levels in the spin resonance feature 12. The resonator device 40 contains at least two stripline resonators, which are operated at different excitation frequencies.

For this purpose, the test device 20 contains one or more signal sources 22, the excitation signals of which, for example, are supplied to the resonator device 40 via a duplexer 24 and there generate alternating magnetic fields with two or more different frequencies for the simultaneous measurement of the spin resonance feature 12 at different frequencies. For this purpose, the test device 20 may contain multiple signal sources with different excitation frequencies or else only a single signal source 22 having an excitation signal with multiple different frequency components, which on account of the special configuration of the stripline resonators generates alternating magnetic fields with different frequencies there. The excitation field typically has frequencies above 1 GHz and is polarized perpendicular to the z direction.

In addition to said elements, the test device 20 includes a detector diode 26 for measuring the high-frequency power reflected by the resonator device 40 and an evaluation unit 28 for evaluating and optionally displaying the measurement result. If the spin resonance feature 12 is in resonance at a coupled-in frequency, the resonator quality changes, and with it the power reflected by the stripline resonators. Due to the modulation of the static polarization field by the modulation device 36, the exact value of the Larmor frequency of the sample oscillates so that the obtained measurement signal is amplitude-modulated with the modulation frequency.

For a more detailed explanation of the special features of the present invention, the upper part of FIG. 2 shows a schematic plan view of a resonator device 40 according to an exemplary embodiment of the invention having a carrier 42, with a first stripline resonator 44 arranged on the carrier having a resonant frequency f_{A} and a second stripline resonator 46 arranged on the carrier having a resonant frequency f_{B}.

As indicated in the lower part of FIG. 2, the polarization device 34 generates a homogeneous polarization field B₀ in the air gap 32, so that the field strength of the polarization field at po-sitions x_{A} and x_{B} of the two stripline resonators 44, 46 is substantially equal in size. Specifically, in the exemplary embodiment, the two pole surfaces 38 of the magnetic core 35 are designed plane-parallel to each other and to the plane of the resonator device 40 and the field strength of the polarization field at the locations x_{A} and x_{B} differs by no more than 2%.

The two stripline resonators 44, 46 are arranged one after the other in the transport direction 14 and are therefore swept over consecutively by the spin resonance feature 12 of the banknote 10 with a time offset. The two stripline resonators 44, 46 both have a square shape, but have different resonance frequencies f_{A}, f_{B} due to their different edge lengths.

For a further explanation of the operating principle of the present invention, the diagram 50 of FIG. 3 shows the simplified spectrum 52 of a spin resonance line, in the present case, for example, the spin resonance line of the spin resonance feature 12 of the banknote 10, as a function of the excitation frequency f at a fixed value of the polarization field B₀. In the curve 52, two characteristic spectral components 54A, 54B are drawn at the above-specified resonance frequencies f_{A} and f_{B} of the two resonators 44 and 46 respectively.

If the resonator device 40 of FIG. 2 is swept over at the polarization field strength B₀ by the banknote 10 with the spin resonance feature 12, each of the two stripline resonators 44, 46 detects the spectral component 54A and 54B of the spin resonance feature 12, which belongs to its resonance frequency f_{A} and f_{B} respectively. Specifically, the stripline resonator 44 at position x_{A} measures the spectral intensity Int(f_{A}) of the spectral component 54A and the stripline resonator 46 at position x_{B} measures the spectral intensity Int(f_{B}) of the spectral component 54B.

As already explained above in essence, in a real authenticity test, the static magnetic field B₀ of the polarization device 34 is additionally varied around the resonance field strength with the aid of a ramp coil and thus the field strength of the polarization field B₀ is traversed at a fixed frequency of the excitation field, to allow the recording of a frequency spectrum of the resonance of the feature 12.

The advantage of embodiments according to the invention is described in more detail with reference to the diagrams 60, 70 of FIG. 4 using the example of a spin resonance feature 12 with only one spin resonance line. The spin resonance line 62 of the feature 12, shown in simplified form in the figures, has, for example, a line width corresponding to the distance from minimum to maximum of 10 mT in the space of the polarization field strength.

If a conventional single resonator with a resonance frequency 64 of f₀=8.41 GHz is used to record the spin resonance spectrum, then at a polarization field strength B₀=300 mT a field ramp 66 over a range of about 40 mT is required for a complete detection of the spectral signature at this line width, as illustrated in FIG. 4(a). The field ramp 66 can be drawn in the diagrams 60, 70, since due to the proportionality of the Larmor frequency of the spin resonance feature to the strength of the polarization field B₀, the frequency spectrum of diagrams 60, 70 corresponds at the same time to a spectrum in the space of the polarization field strength. Since the Larmor frequency is proportional to the polarization field strength, at a high field strength the fixed excitation frequency is lower than the Larmor frequency and at a low field strength the fixed excitation frequency is greater than the Larmor frequency.

In the exemplary embodiment of FIG. 4, for example, at a polarization field strength of B₀=300 mT, the excitation frequency of 8.41 GHz corresponds exactly to the Larmor frequency of the spin resonance feature 12 to be tested. As can be seen from FIG. 4(a), a field ramp 66 with an amplitude from −20 mT to +20 mT must be traversed around the resonance field strength in order to be able to completely measure the spin resonance line 62 with its line width of 10 mT at a fixed excitation frequency. Such a field ramp is associated with long measuring times and a high current requirement.

If, on the other hand, a resonator device with multiple stripline resonators of different resonance frequencies according to the present invention is used for recording the spectrum, a significantly shorter measuring time and a significantly lower current requirement can be achieved.

With reference to FIG. 4(b), the resonator device of a sensor element according to the invention contains, for example, five stripline resonators spaced one after the other in the transport direction with the resonance frequencies f_{A}=7.96 GHZ, f_{B}=8.18 GHZ, f_{C}=8.41 GHZ, f_{D}=8.63 GHz and f_{E}=8.85 GHz. The resonance frequency f_{C} of the central stripline resonator corresponds to the resonance frequency f₀ of the single resonator of FIG. 4(a) and exactly to the center frequency of the spin resonance line 62 at the polarization field strength B₀=300 mT.

With the resonator device 40, therefore, at a fixed value of the polarization field strength B₀ the intensity can be measured at five different frequencies f_{A} to f_{E} simultaneously. The frequencies f_{A} to f_{E} are shown in FIG. 4(b) with dashed lines.

In order to be able to measure the spin resonance line 62 with its line width of 10 mT completely, an additional field ramp 78 is also required here. However, as can also be seen from FIG. 4(b), here a substantially smaller field ramp 78 with an amplitude of only about-3.5 mT to 3.5 mT, corresponding to about one fifth of the amplitude of the conventionally required field ramp 66 of FIG. 4(a), is sufficient to completely record the spectral signature of the spin resonance line 62.

Since the polarization field in the air gap is homogeneous and the polarization field strength B₀ is therefore the same for all five stripline resonators, the polarization field strength B₀=300 mT is indicated on the upper axis of the diagram 70 at the resonance frequencies f_{A} to f_{E}. The arrows of the field ramp 78 indicate the sampling of the shape of the spectral line 62 by the field ramp 78 with a total amplitude of approximately 7 mT. By simultaneously measuring at five frequencies, the spectral line 62 can be measured at the same spectral resolution with a significantly shorter measurement time and thus a significantly lower current requirement.

In the exemplary embodiment shown in FIG. 2, for illustration purposes the resonator device contains only two stripline resonators, but it is understood that a larger number of stripline resonators can also be used to achieve, in particular, a better spectral resolution, as explained, for example, in connection with FIG. 4.

In the exemplary embodiments described so far, the stripline resonators serve to detect the spectral components of a single spin resonance line. If the banknote 10, or generally a data carrier to be tested, is equipped with a spin resonance feature that shows multiple spectral lines, the resonator device can be readily provided with additional stripline resonators which detect spectral components of the additional lines.

The individual stripline resonators of a resonator device according to the invention can be operated by means of independent signal sources. However, this also requires that the resonators are connected to independent signal branches, which requires, in particular with a large number of resonators, a large installation space for the circuit implementation.

FIG. 5 shows an alternative circuit 80 for connecting a resonator device 40 of a sensor element 30 according to the invention to only one single signal branch. All stripline resonators 44, 46 of the resonator device 40 are connected to this signal branch, so that the required installation space is small. For the sake of simplicity, only two resonators 44, 46 are shown in the circuit 80 of FIG. 5. By parallelizing further excitation sources and reception mixers, the number of resonators can be readily increased as desired.

The circuit 80 of FIG. 5 is divided into an excitation circuit 82 and a reception circuit 84. Furthermore, the circuit is divided into a digital part and an analog part. The separation takes place here in the digital-to-analog (D/A) or analog-to-digital (A/D) converters shown. The digital part of the circuit can be advantageously implemented using an FPGA. This makes it a simple matter to add additional signal sources and reception mixers.

In the analog part of the circuit there is a high-frequency source 86, which provides a signal at a carrier frequency that approximates to the resonance frequencies of the multiple resonators. For example, it may correspond to the mean value of the resonance frequencies, or it may be slightly lower than the lowest resonance frequency. In particular, the carrier frequency is in the GHz range.

In the FPGA there are multiple signal sources 22, which are operated in the baseband of the circuit 80, i.e. at low frequencies, for example in the range of several kHz to 1 GHz. Preferably, the frequency of a signal source 22 has a fixed frequency interval with respect to the resonance frequency of the associated resonator. This frequency interval is preferably the same for all pairs of signal sources and resonators and is defined by the carrier frequency.

The signal sources 22 are added, subjected to a D/A conversion and then mixed upwards with the high-frequency carrier 86. For better clarity, no filter banks are drawn in the figure. After signal amplification, the bandpass signal thus obtained is fed to a circulator 88. If the frequencies of the individual signal sources 22 are matched with the carrier frequency and the respective resonance frequencies f_{A}, f_{B}, the individual spectral components of the bandpass signal are divided over the respective resonators 44, 46, since each resonator can only be excited efficiently at its resonance frequency.

For example, the two signal sources 22 located in the FPGA can be operated at 100 MHz and 700 MHz respectively. A subsequent mixing with a radio frequency carrier 86 of the frequency 9.0 GHz allows the coupling of a 9.1 GHz and a 9.7 GHz resonator.

The signal reflected from the resonators 44, 46 is fed via the circulator 88 to a receiver amplifier, mixed downwards (phase shifters are not shown for simplicity) and subjected to an A/D conversion. Further signal processing, e.g. a lock-in detection of the field modulation, can then be carried out in the FPGA. The figure shows, for example, two evaluation units 90 for the evaluation of the response signals of the tested spin resonance feature obtained at the excitation frequencies f_{A}, f_{B}.

In order to demonstrate the operation of the invention, the behavior of a sensor element with a resonator device having two square 2/2 stripline resonators according to FIG. 2 was simu-lated.

The stripline resonators 44, 46 are mounted on a printed circuit board 42 with thickness of 1.5 mm, the dielectric constant of which is 3.66. The resonators 44, 46 are at a distance of 15 mm along the banknote transport direction 14. The edge length of the first resonator 44 is 8.1 mm, corresponding to a resonance frequency of f_{A}=8.8 GHZ, the edge length of the second resonator is 7.1 mm, corresponding to a resonance frequency of f_{B}=9.8 GHz.

The two resonators 44, 46 are operated by circulators with independent 50-Ω signal sources running with equal power in continuous wave (CW) mode at the respective resonance frequency. To connect to the signal source, the impedance of the resonators is transformed to 50 Ω using a λ/4 transformer.

The resonator device 40 thus constructed is installed in the air gap of a magnetic circuit in which a homogeneous polarization field with a strength of 300 mT is generated.

Subsequently, a paper sample of length 100 mm was homogeneously loaded over its surface with a spin resonance feature, the spectrum 112 of which is illustrated in the diagram 110 of FIG. 6. The resonance frequencies f_{A} and f_{B} of the two resonators 44, 46 and the associated rela-tive signal intensities Int(f_{A}) and Int(f_{B}) are also shown.

The paper sample with this spin resonance feature is transported through the resonator device 40 and the signal intensity of the spin resonance feature is recorded with the two resonators 44, 46. The signal curves 122A (resonator 44) and 122B (resonator 46) obtained are illustrated in the diagram 120 of FIG. 7, which shows the measured signal intensities as a function of the location x. The signal curves were normalized to the mean signal intensity of the signal curve 122A.

By averaging the signal intensity in the plateau region of each signal curve 122A, 122B, a ratio of the signal intensity of the first resonator 44 to the signal intensity of the second resonator 46 of 1.0/−0.85 is obtained, which matches very closely the ratio Int(f_{A})/Int(f_{B}) expected from the resonance spectrum of FIG. 6.

In the arrangements described so far, the stripline resonators of the resonator device are designed such that their resonance frequency is essentially within the line width of the spin resonance line to be measured. However, it is also possible to provide a stripline resonator in the resonator device, the resonance frequency of which corresponds to none of the expected Larmor frequencies. With such a resonator, a negative proof can then be carried out, that is, for a real banknote no spin resonance signal is expected for this resonator.

### LIST OF REFERENCE SIGNS

10 banknote test specimen
12 spin resonance feature
14 transport path
20 test device
22 signal source
24 duplexer
26 detector diode
28 evaluation unit
30 sensor element
32 air gap
34 polarization device
35 magnetic core
36 modulation device
38 pole surfaces
40 resonator device
42 carrier
44, 46 stripline resonators
50 diagram
52 spectrum of a spin resonance line
54A, 54B spectral components
60 diagram
62 spin resonance line
64 resonance frequency
66 field ramp
70 diagram
78 field ramp
80 circuit
82 excitation circuit
84 reception circuit
86 high-frequency carrier
88 circulator
110 diagram
112 spectrum of the spin resonance feature
120 diagram
122A, 122B signal curves

1.-19. (canceled)

20. A sensor element for checking a flat-surface data carrier having a spin resonance feature, with
a magnetic core with an air gap into which the flat-surface data carrier can be inserted for testing,
a polarization device for generating a static magnetic flux in the air gap, and
a resonator device for exciting the spin resonance feature of the data carrier to be tested in the air gap,
wherein the resonator device contains at least two stripline resonators, which are designed and configured to be operated at different excitation frequencies.

21. The sensor element according to claim 20, wherein the stripline resonators of the resonator device are arranged in the form of a one-dimensional array.

22. The sensor element according to claim 20, wherein the stripline resonators of the resonator device all have different resonance frequencies.

23. The sensor element according to claim 20, wherein the stripline resonators are geometrically similar, that is, they have the same shape but different sizes.

24. The sensor element according to claim 20, wherein the air gap is bounded by two plane-parallel pole surfaces of the magnetic core.

25. The sensor element according to claim 20, wherein the polarization device generates a static magnetic flux in the air gap, which has substantially the same strength at the location of each of the stripline resonators in that the static magnetic flux at the location of the stripline resonators has a maximum deviation of 2%.

26. The sensor element according to claim 20, wherein the stripline resonators are designed with a flat surface having a main extension plane which is plane-parallel to at least one of the pole surfaces of the magnetic core bounding the air gap.

27. The sensor element according to claim 20, wherein the sensor element has a modulation device for generating a time-varying magnetic modulation field in the air gap,
wherein the modulation frequency at the location of each of the stripline resonators of the resonator device is equal.

28. The sensor element according to claim 27, wherein the modulation device is formed by a single modulation coil arranged in the air gap.

29. The sensor element according to claim 20, wherein the stripline resonators are designed with a flat surface having a main extension plane which is perpendicular to the direction of the static magnetic flux generated by the polarization device.

30. The sensor element according to claim 20, wherein the air gap has a height of less than 10 mm.

31. The sensor element according to claim 20, wherein the sensor element has a ramp coil for generating a ramp function of the static magnetic flux.

32. The sensor element according to claim 20, wherein the stripline resonators of the resonator device form a multi-track arrangement with a plurality of parallel tracks, in which each track is formed by a one-dimensional array of stripline resonators.

33. A test device for testing a flat-surface data carrier having
a sensor element according to claim 20, and
either a plurality of signal sources having different excitation frequencies, from which the stripline resonators of the resonator device are fed,
or a single signal source having an excitation signal with a plurality of different frequency components, from which the stripline resonators are fed.

34. The test device according to claim 33, having a transport device, which guides the flat-surface data carriers to be tested along a transport path through the air gap of the magnetic core,
wherein the transport device is advantageously designed and configured for fast-running transport of the flat-surface data carriers to be tested along the transport path.

35. A method for testing a flat-surface data carrier having a spin resonance feature, by means of a sensor element or a test device according to claim 33,
wherein in the method
a flat data carrier to be tested is guided along a transport path through the air gap of the magnetic core of said sensor element,
wherein a plurality of stripline resonators of the resonator device is located one after the other parallel to the transport path,
a static magnetic flux is generated using the polarization device and a time-varying magnetic modulation field is generated in the air gap using a modulation device, and
the resonator device is used to excite the spin resonance feature of the data carrier to be tested.

36. The method according to claim 35, wherein
the data carrier to be tested is guided past the consecutively located stripline resonators and a time series of measurements of the response signal of the spin resonance feature generated after each excitation is recorded by the stripline resonators,
measurement data corresponding to the same measuring spot are identified from the time series of measurements of the stripline resonators,
spectral information relating to the spin resonance feature is derived from the identified measurement data, and
the data carrier is evaluated on the basis of the derived spectral information.

37. The method according to claim 35, wherein the measured data are spatially resolved or spatially averaged.

38. The method according to claim 35, wherein
a spatially homogeneous ramping field is superimposed on the static magnetic flux so that the total static magnetic flux in the air gap varies over time between a minimum value and a maximum value,
the spectral information is derived from the identified measurement data, taking into account the field strength of the static magnetic flux at the respective measurement time, and
based on the derived spectral information, the authenticity of the tested data carrier and/or the membership of the tested data carrier of one of a plurality of data carrier classes with different spectral signatures is determined.
